(19) United States
(12) Patent Application Publication
(10) Pub. No.: US 2005/0147740 A1
(43) Pub. Date: Jul. 7, 2005

(54) Method of applying a cover layer to a structured base layer

(75) Inventor: Michael Agater, Lauenau (DE)

Correspondence Address: CROWELL & MORING LLP;INTELLECTUAL PROPERTY GROUP, P.O. BOX 14300, WASHINGTON, DC, 20044-4300, US

(73) Assignee: LPKF Laser & Electronics AG, Garbsen (DE)

(21) Appl. No.: 11/006,622

(22) Filed: Dec. 8, 2004

(30) Foreign Application Priority Data
Dec. 8, 2003 (DE) 103 57 525.1

(51) Int. Cl. H05K 3/00

(52) U.S. Cl. 427/96.1

(57) ABSTRACT

A method for applying a cover layer (1) to a base layer (2) which is provided with structuring (3) determined, for example, by printed conductors. The base layer (2) is moved continuously at a feed rate (v) in continuous operation. A guide (4) constructed as a rotatable body, brings the cover layer (1) to the matching feed rate (v) and applies the cover to the base layer (2). To optimize the application of the cover layer (1) to the structure (3) on the base layer (2), and in particular to prevent inaccuracies in the correlation between the cover layer (1) and the base layer (2) while at the same time permitting increased flexibility in manufacturing, the position of the structuring (3) is determined first by a non-contact sensor (5) immediately upstream of the guide (4). Then a signal for a laser (6) is triggered by a control unit (9). Depending on the position of the structuring (3), a recess is then created in the cover layer (1) by the laser (6), and the recess is thereafter made to correspond to the structuring (3).

### BACKGROUND OF THE INVENTION

The present invention relates to a method of applying a cover layer to a base layer which has a structured surface and is moving continuously or discontinuously at a feed rate, in which the cover layer, moving at a matching feed rate is applied to the base layer by a guide.

A method of this type is known, for example, from U.S. Pat. No. 6,461,527 (=DE 19929179) and is used in practice, for example, to produce a multilayer structure. With the roll-to-roll method described in that patent, the base layer, having discrete structuring at intervals, is moved at a constant feed rate in particular. The flexible cover layer is fed onto the base layer at the same feed rate as the base layer and thereby partially wraps around a pressure roll whose circumferential speed corresponds to the feed rate. Between the base layer and the pressure roll, the cover layer is applied to the base layer and bonded to it. Localized ablation of the base layer material is then performed by treating the base layer with a laser beam to produce a contact recess.

In practice, it is also known that openings can be provided in the cover layer by a rotary cutting blade before bringing the layers together, so that selected areas of the base layer can be cut out in a targeted manner.

It is important in this method to ensure reliable synchronization between the structuring of the base layer and the openings in the cover layer.

Because of the path-dependent correlation between the base layer and the cover layer, the desired synchronization is essentially independent of the feed rate, so that the relative position determination must be performed only at the beginning of the cover layer or the base layer. In practice, however, unavoidable elongation in length of the cover layer or the base layer has proven to be problematical, so that there may be deviations in the correlation between the opening and the structuring. At the same time, these deviations also lead to deviations in the subsequent structuring.

To counteract this problem, it is already known that stretching or elongation may also be induced in every other layer in each case to restore the desired synchronization. However, this method is complex and cannot always prevent the occurrence of errors and thus cannot prevent rejects.

Another problem is that the contours of the passage cannot be selected at will by the rotary cutting blade because the areas to be removed are separated cohesively as a film from the cover layer. In particular, therefore, it is impossible to implement openings in the form of “islands” without any connection to the subsequent opening.

Furthermore, production of the altered structuring necessitates shutdown and renewed setup of the equipment. In particular, production of different structuring and different passages accordingly can be performed only to an extremely limited extent and the production of individual structuring is completely impossible.

Furthermore, it is known from U.S. Pat. No. 5,800,724 that a substrate wrapped partially around a roll may be joined to a metal foil. Before applying the metal foil, the substrate is provided with an adhesive in targeted areas. The bonding layer of the substrate and the metal film is then provided with openings using a laser cutting device, whereby the cut out particles are removed by an exhaust venting system.

Continuous application of a cover layer to a base layer is also disclosed by German Patent 39 22 478 A1 and U.S. Pat. No. 6,662,439 (=WO 01/25775).

### SUMMARY OF THE INVENTION

Accordingly, it is an object of the invention to provide an improved method for applying a cover layer to a base layer having a structured surface.

Another object of the invention is to optimize a generally known method for applying a cover layer to a base layer having a structured surface.

A particular object of the invention is to provide a method for applying a cover layer to a base layer in which inaccuracies in the correlation between the cover layer and the base layer are prevented.

It is also an object of the invention to provide a method for applying a cover layer to a base layer which facilitates flexibility in manufacturing processes.

These and other objects are achieved in accordance with the present invention by providing a method of applying a cover layer to a base layer which has a structured surface, the method comprising moving the base layer at a first feed rate (v); moving the cover layer at a second feed rate which matches the first feed rate; and applying the cover layer to the base layer via a guide; wherein in order to achieve a desired synchronization the method further comprises prior to the application of the cover layer to the base layer the steps of: determining the position of the structure on the structured surface of the base layer via a sensor; utilizing positional information from the position determination of the structure to trigger a laser control signal, and controlling a laser in response to the control signal to create a recess in the cover layer in a position corresponding to the position of the structure on the base layer, whereby the structure is received in the recess when the cover layer is applied to the base layer.

Further preferred features and aspects of the invention are also described hereinafter.

Thus, according to this invention, a method is provided with which in order to achieve the desired synchronization, first the position of the structuring of the base layer is determined by a sensor and then a control unit triggers a signal and a laser creates a recess in the corresponding position in the cover layer. This invention is based on the consideration that the correlation and synchronization of the recesses in the cover layer with the structuring of the base layer can be performed without error if the provided recess is introduced based only on the measured position of the structuring of the base layer. The use of the laser also makes it possible for the first time to achieve almost any contours of the recesses so that in particular island-shaped recesses are also possible without difficulty. In addition, changes in structuring or in the spacing between successive structures can be achieved in a flexible manner without shutdown of the plant, so that manufacturing cost is greatly reduced.

A refinement of this invention, in which the forward movement of the base layer is detected by an additional displacement sensor, has proven to be especially advantageous. In this case the base layer is connected to a signal generator for a reference signal so that the forward movement is reliably determined by this displacement sensor, in particular incrementally. The path-dependent correlation between the base layer and the cover layer can thus be verified.

A particularly advantageous embodiment is achieved when in addition to the position determination, the control unit also identifies the structure and causes a corresponding recess to be introduced. In this way it is possible for the first time to create an individual manufacturing program by identifying the structuring through an analytical comparison with stored features and by selecting a corresponding laser control program for the recess. In particular, different successive structurings may also be combined into units.

In an embodiment of the invention which is of particular practical relevance, the structure on the base layer is formed by a plurality of discrete printed conductors.

The method of the invention can be carried out in discontinuous operation. However, it has proven to be particularly advantageous to apply the cover layer provided with the recesses in a continuous operation. This permits a significant reduction in manufacturing time. In particular, the feed rate can be greatly increased because of the path-dependent correlation.

It has proven to be particularly useful in actual practice if the position of the structuring of the base layer is determined in a non-contact procedure, in particular by using a CCD sensor, so that retroactive effects on the forward feed of the base layer are ruled out. The position may be reliably determined even at high feed rates, and the features can be analyzed for quality assurance purposes.

Another especially advantageous embodiment is achieved by readjusting the laser beam according to the feed rate of the cover layer to thereby further reduce manufacturing time. Furthermore, additional lasers may be used to further optimize the creation of the recesses.

Therefore, the recess may also be ablated according to the projection principle or ablated through a mask positioned between the laser and the cover layer so that the recesses can be produced by a single laser pulse.

In this way, openings may be created in the cover layer by the laser or a recess may be introduced by creating cavities in the cover layer with the laser so that a hollow space is delineated between the base and the cover layer.

For example, using the method of the invention, substances or devices that interact with the structuring of the base layer and are highly miniaturized may be introduced into the hollow space.

It is also especially advantageous if the material, e.g., solid particles or gas, which is removed by the laser to create the recess in the cover layer carried off by suction to thereby ensure a reliable removal of the substances and prevent possible interfering effects.

In another particular embodiment of the method in which the cover layer is applied to the base layer with a predetermined contact pressure applied through a rotating body. The rotating body may be constructed as a hollow body or in multiple parts in order to facilitate the suction or vacuum collection of removed material.

In one particularly advantageous embodiment of the invention, the base layer and/or cover layer is a film which allows winding and unwinding from one roll to the next. This can greatly facilitate subsequent manufacturing processes because of the units available on the roll.

In order to permanently join the layers, it is possible to modify the method so that the base layer and the cover layer are welded together or glued together to form an inseparable layer structure. Welding and or adhesive bonding techniques are considered especially suitable for permanent joining of the layers.

Essentially any laser may be used as the laser light source. Examples of particularly suitable lasers include excimer lasers, CO₂ lasers or Nd:YAG lasers.

### BRIEF DESCRIPTION OF THE DRAWINGS

The invention will be described in further detail hereinafter with reference to an illustrative preferred embodiment shown in the accompanying drawing figures in which:

FIG. 1 is a schematic representation of the application of a cover layer to a base layer in accordance with the present invention; and

FIG. 2 is an enlarged schematic diagram of the base layer with the cover layer applied to it taken from area II of FIG. 1.

### DETAILED DESCRIPTION OF PREFERRED EMBODIMENTS

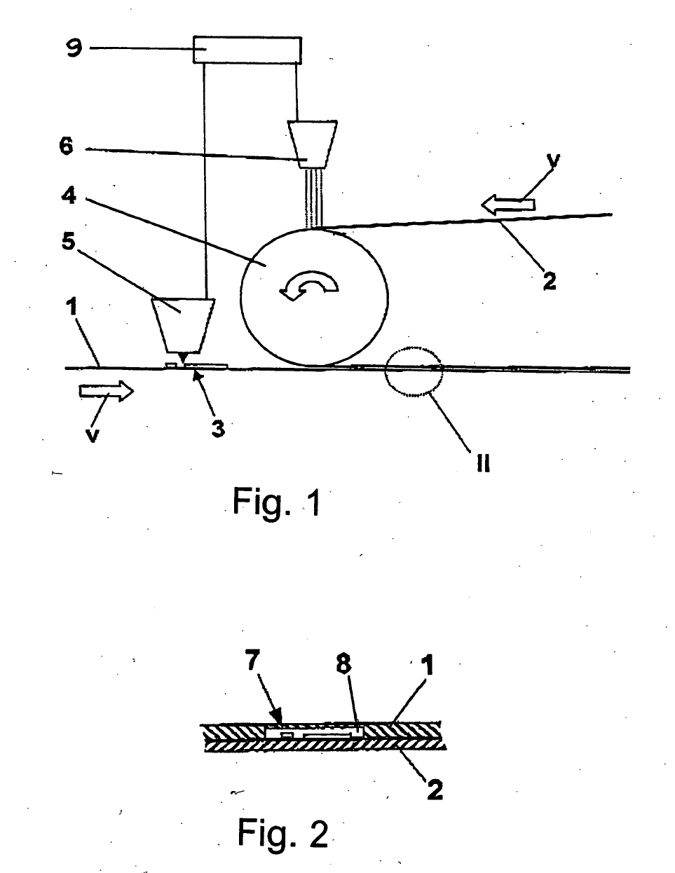

FIG. 1 shows a method of applying a cover layer 1 to a base layer 2, which is provided with a structuring 3 comprised of printed conductors, for example. The base layer 2 is moving at a feed rate v in continuous operation. By means of a guide 4, which is designed as a rotatable body, the cover layer 1 is brought to the matching feed rate v and is applied to the base layer 2. The position of the structuring 3 on base layer 2 is determined directly by a non-contact sensor 5 and transmitted to a control unit 9. The control unit uses this information to trigger a control signal for a laser 6 which ablates the cover layer 1 to form a recess in precise position to receive the structure 3 when the cover layer 1 is applied to the base layer 2. Thus, depending on the position of the structuring 3, a recess 7 (shown in FIG. 2) is created by the laser 6 in the cover layer 1 and is made to coincide with the structuring 3.

FIG. 2 shows an enlarged diagram with the base layer 2 with the cover layer 1 applied to it. This also shows a hollow space 8 which is delineated by a recess 7 between the base layer 2 and the cover layer 1.

The foregoing description and examples have been set forth merely to illustrate the invention and are not intended to be limiting. Since modifications of the described embodiments incorporating the spirit and substance of the invention may occur to persons skilled in the art, the invention should be construed broadly to include all variations within the scope of the appended claims and equivalents thereof.

1. A method of applying a cover layer to a base layer which has a structured surface, said method comprising moving said base layer at a first feed rate (v); moving the cover layer at a second feed rate which matches said first feed rate; and applying the cover layer to the base layer via a guide; wherein in order to achieve a desired synchronization said method further comprises prior to the application of the cover layer to the base layer the steps of: determining the position of a structure on the structured surface of the base layer via a sensor; utilizing positional information from the position determination of the structure to trigger a laser control signal, and controlling a laser in response to said control signal to create a recess in said cover layer in a position corresponding to the position of said structure on said base layer, whereby said structure is received in said recess when said cover layer is applied to said base layer.

2. A method according to claim 1, further comprising detecting the forward movement of the base layer with a displacement sensor.

3. A method according to claim 1, wherein the shape of the structure is also determined, and the recess in the cover layer is created with a corresponding shape.

4. A method according to claim 1, wherein the structure on the base layer comprises a plurality of discrete printed conductors.

5. A method according to claim 1, wherein the cover layer is applied to the base layer in a continuous operation.

6. A method according to claim 1, wherein the position of the structure on the base layer is determined by a non-contact method.

7. A method according to claim 6, wherein the position of the structure on the base layer is determined with a CCD sensor.

8. A method according to claim 1, further comprising adjusting the laser output in accordance with the feed rate of the cover layer.

9. A method according to claim 1, wherein the recess is ablated according to the projection principle.

10. A method according to claim 1, wherein the recess is ablated through a mask positioned between the laser and the cover layer.

11. A method-according to claim 1, wherein openings are created in the cover layer by the laser.

12. A method according to claim 1, wherein the recess comprises a cavity created in the cover layer by the laser, whereby a hollow space is created between the base layer and the cover layer.

13. A method according to claim 1, wherein material released from the cover layer by the laser in creating the recess is removed by suction.

14. A method according to claim 1, wherein the cover layer is applied to the base layer with a predetermined contact pressure by a rotating body.

15. A method according to claim 1, wherein the base layer comprises a film.

16. A method according to claim 1, wherein the cover layer is a film.

17. A method according to claim 1, wherein the base layer and the cover layer are welded or glued together.

18. A method according to claim 1, wherein said laser is an excimer laser, a CO₂ laser or an Nd:YAG laser.
